(19) United States
(12) Patent Application Publication
(10) Pub. No.: US 2026/0271216 A1
(43) Pub. Date: Sep. 10, 2026

(54) TEST SYSTEM RACK WITH MODULAR POWER INFRASTRUCTURE

(71) Applicant: NATIONAL INSTRUMENTS CORPORATION, Austin, TX (US)

(72) Inventors: Cheng Yung Sheng, Butterworth (MY); Russell Bohacek, Dripping Springs, TX (US); Lee Say Chun, Bayan Lepas (MY); Tan Chin Cheang, Bukit Mertajam (MY)

(21) Appl. No.: 19/070,615

(22) Filed: Mar. 5, 2025

(51) Int. Cl. H05K 7/14; H05K 7/16; H05K 7/18

(52) U.S. Cl. CPC H05K 7/1492; H05K 7/1489; H05K 7/16; H05K 7/183

(57) ABSTRACT

A test system rack or cabinet includes a housing containing instruments or equipment in a plurality of vertically stacked horizontal rows, and a side space arranged on a first side of the housing. The side space includes a plurality of mounting rails configured to house a plurality of power supplies in a modular fashion. The rack further includes a hinged bracket configured to pivot the side space away from the housing to provide access to the instruments, equipment, and/or the power supplies without removing them from the housing or the side space.

### BACKGROUND

### Technical Field

The present invention relates generally to racks and cabinets for housing and powering test systems, instruments, and equipment.

### Description of the Related Art

Various types of electronic devices may be mounted in a test system rack or cabinet in order to facilitate interfacing with the devices, containing the devices, managing the devices, or other reasons. These devices often utilize dedicated power sources for their operation, which may also be housed within the test system rack or cabinet. Housing the power supplies in the rack or cabinet may present difficulties for access and/or reduce available space for test equipment. Accordingly, improvements in the field are desired.

### SUMMARY

Embodiments herein describe test system racks and cabinets configured to house and provide power to test instruments and/or equipment, and methods for operating said racks and cabinets.

In some embodiments, a rack includes a housing configured to contain one or more instruments or equipment in a plurality of vertically stacked horizontal rows. The rack further includes a side space arranged on a first side of the housing. The side space is configured to house a plurality of power supplies, and the side space and the housing may have substantially the same height and depth.

In some embodiments, the side space includes a plurality of mounting rails configured to house the plurality of power supplies in a modular fashion.

In some embodiments, the rack further includes a hinged bracket configured to pivot the side space away from the housing. Pivoting the side space away from the housing may provide access to the instruments, equipment, and/or power supplies without removing the instruments or equipment from the housing or the power supplies from the side space.

In some embodiments, the side space has a thickness substantially close to two standardized rack units, and the horizontal rows are stacked with a vertical spacing of one standardized unit.

This Summary is intended to provide a brief overview of some of the subject matter described in this document. Accordingly, it will be appreciated that the above-described features are only examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

FIGS. 1A-C illustrate an isometric view of a test rack with a side space on hinged pivots, according to some embodiments; and

FIGS. 2A and 2B illustrate isometric and head-on views, respectively, of another test rack that includes a side space, according to some embodiments.

While the invention is susceptible to various modifications and alternative forms, specific embodiments thereof are shown by way of example in the drawings and are herein described in detail. It should be understood, however, that the drawings and detailed description thereto are not intended to limit the disclosure to the particular form disclosed, but on the contrary, the intention is to cover all modifications, equivalents and alternatives falling within the spirit and scope of the present disclosure, including the appended claims. Particular features, structures, or characteristics may be combined in any suitable manner consistent with this disclosure.

It is to be understood that the terminology used herein is for the purpose of describing particular embodiments only, and is not intended to be limiting. As used herein, the singular forms “a”, “an”, and “the” include singular and plural referents unless the content clearly dictates otherwise. Furthermore, the words “can” and “may” are used throughout this application in a permissive sense (i.e., having the potential to, being able to), not in a mandatory sense (i.e., must). The term “include,” and derivations thereof, mean “including, but not limited to.” The term “coupled” means directly or indirectly connected.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “mobile device configured to generate a hash value” is intended to cover, for example, a mobile device that performs this function during operation, even if the device in question is not currently being used (e.g., when its battery is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed mobile computing device, for example, would not be considered to be “configured to” perform some specific function, although it may be “configurable to” perform that function. After appropriate programming, the mobile computing device may then be configured to perform that function.

Reciting in the appended claims that a structure is “configured to” perform one or more tasks is expressly intended not to invoke 35 U.S.C. § 112(f) for that claim element. Accordingly, none of the claims in this application as filed are intended to be interpreted as having means-plus-function elements. Should Applicant wish to invoke Section 112(f) during prosecution, it will recite claim elements using the “means for” [performing a function] construct.

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

### DETAILED DESCRIPTION

Instruments for collecting data or information from an environment or unit under test may be coupled to and controlled by computer systems. Data collected by these instruments may be used to control units being tested (e.g., an overheated unit may be shutdown) or an environment (e.g., ventilation systems may be activated if a certain chemical is detected in the air). Data may also be displayed to a user for control and/or experimental purposes (e.g., to improve the design of the unit being tested). Instruments and/or computer systems may also perform various data analysis and data processing on acquired data prior to control of the unit and/or display of the data to the user. Examples of various types of instruments include oscilloscopes, digital multimeters, pressure sensors, etc., and the types of information that might be collected by respective instruments include voltage, resistance, distance, velocity, pressure, oscillation frequency, humidity or temperature, among others.

Instrumentation systems such as those described above may run on a platform such as Peripheral Component Interconnect (PCI) eXtensions for Instrumentation (PXI). PXI may combine a high-speed PCI bus with integrated timing and triggering features designed for measurement and automation applications to deliver performance improvements over other architectures. PXI may be built on a modular and scalable CompactPCI specification and the high-speed PCI bus architecture.

Any of these types of instruments and equipment, as well as other devices, may be housed in a rack or cabinet where they are affixed to rails and arranged in a vertical stack of horizontal rows. Embodiments herein describe improved designs for such a test system rack or cabinet.

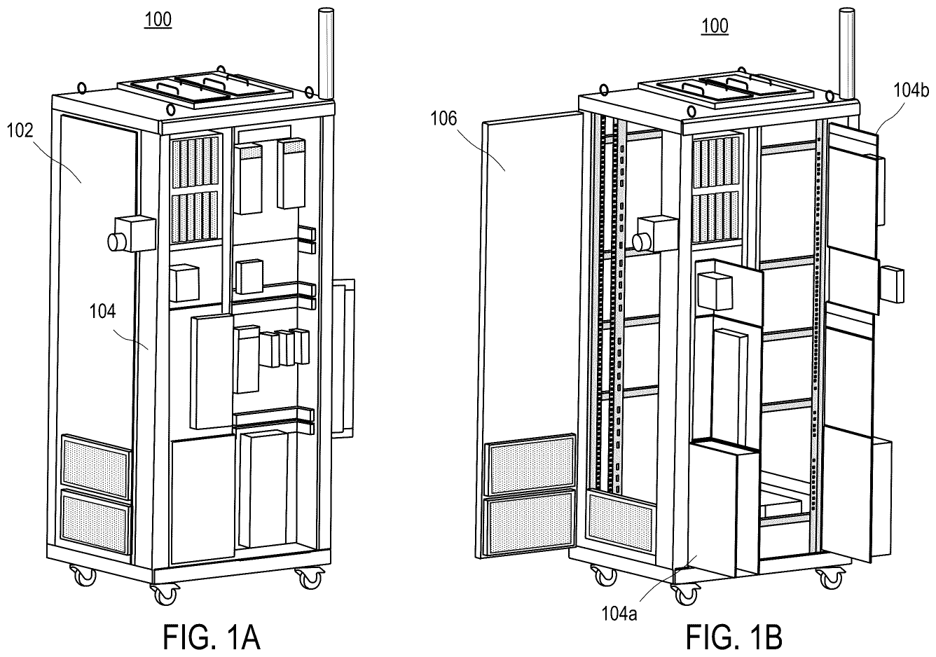

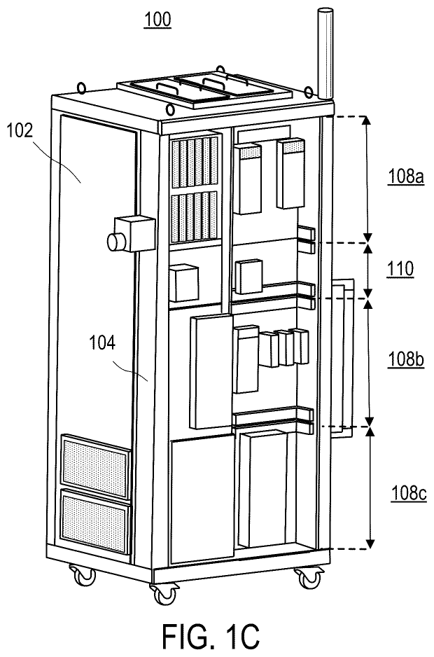

### FIGS. 1A-B and 2A-B—Test System Rack With Side Space

FIGS. 1A-B illustrate a test system rack 100 that includes both a primary housing 102 for accommodating test equipment and a side space 104, according to some embodiments. FIG. 1A shows the test system rack with the side space pivoted adjacent to the housing, whereas FIG. 1B shows a configuration where the side space is pivoted away from the housing via hinges, to provide easier access to power supplies housed in the side space and/or test instruments housed within the primary housing. The rack shown in FIG. 1B has the side space split into two halves, which are attached to the housing via two respective hinged brackets on the left (104a) and right (104b) sides of the rack. In other embodiments, the entire side space may hinge on a single bracket, e.g., on the left or right side only (not illustrated). FIG. 1C additional illustrates how one side of the housing 106 may also be attached via a hinged bracket, so that the side of the housing may also pivot away from the rack to provide easier access to the test equipment.

FIG. 1C illustrates how the side space 100 may be divided into modular compartments to house standardized power equipment. As illustrated, the side space shown in FIG. 1C has six larger compartments (two side-by-side at each of the heights marked 108a, 108b, and 108c) as well as two smaller compartments (two side-by-side at the height marked 110). Each of the six larger compartments (and similarly, each of the two smaller compartments) may be substantially identical in terms of volume and mounting hardware to allow a given type of power output device to be installed in any these spaces to suit customer need in terms of cable routing and outputs. Note that, as used herein, “substantially identical” means that the compartments are of a sufficiently similar size and shape such that they are functionally identical for their intended purpose. For example, two compartments that are substantially identical in size may be sufficiently similar such that they are able to house the same types and/or model(s) of power supplies. For example, power output devices may be able to swap locations between the six larger compartments, or between the two smaller compartments.

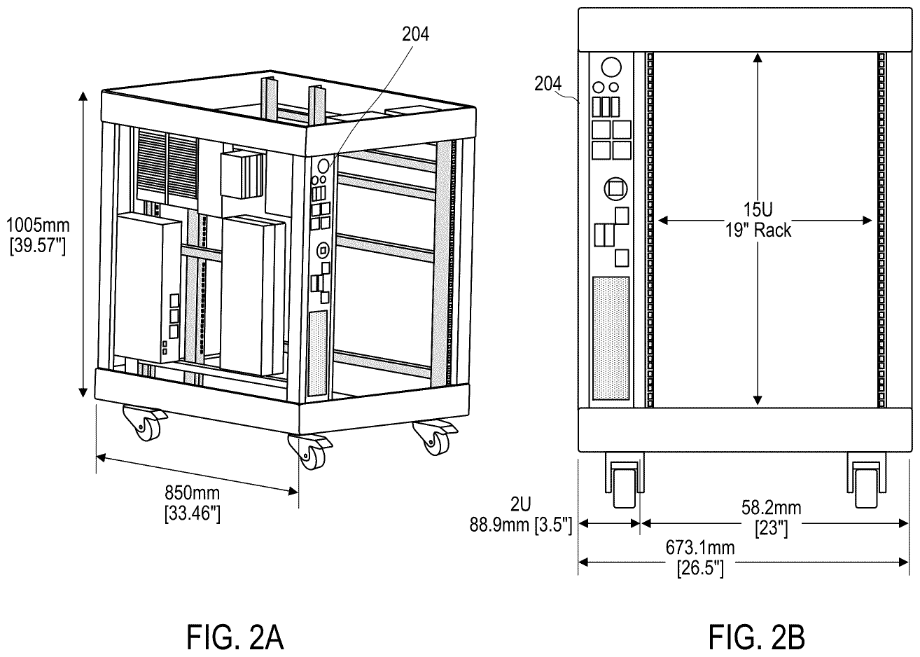

FIGS. 2A and 2B illustrate isometric and head-on views, respectively, of another test rack that includes a side space 204, according to some embodiments. FIGS. 2A-2B illustrate a set of example measurement dimensions for the different portions of the rack. The illustrated dimensions are illustrative only, and other dimensions may also be used, as desired.

The primary housing may be configured to contain one or more test instruments or equipment affixed to rails and arranged in a vertical stack of horizontal rows.

Embodiments herein describe a variety of racks or cabinets configured with modular power infrastructure housed within the side space. In some embodiments, the side space is a 2U side space, with a thickness of two standardized rack units. Note that “U” refers to the industry standard rack size, which as of 2025 is currently 1.75 inches. While some embodiments herein describe system racks that are configured according to this standardized size, it is within the scope of the present disclosure to provide system racks with side spaces of other sizes.

Many existing 19-inch racks in the market house the power infrastructure in the primary rack space, which limits the usable U space for the customer and may potentially obstruct air flow. Embodiments herein improve on these designs and enable all the power infrastructure to be installed in an additional 2U-thickness side space to increase the available volume of the primary U space and the power output.

In some embodiments, a hinged bracket design is utilized to provide accessibility to the primary rack space and/or the power supplies, to enable easy serviceability and assembly while all the devices are still attached to the bracket. As shown in FIGS. 1A-B, one vertical edge of the side space may be attached to the housing via a hinged bracket, which may allow the side space to pivot away from the housing around a vertical axis. This may provide easier access to both the power components within the side space and the test instruments in the main housing, to facilitate installation, configuration, and/or repairs. In addition, the hinged bracket design may act as a firewall to streamline airflow in the primary rack while providing a secondary airflow path to cool the side space. In some embodiments, the hinged bracket may be a mounting bracket configured to mount (house) a power supply, where the hinged mounting bracket is configured to pivot the power supply away from the housing while holding the power supply.

In some embodiments, the side space houses a power entry panel (PEP) that is configured to route power to alternating current (AC) power distribution units (PDUs) and/or direct current (DC) PDUs, which may also be housed within the spacing. Note that PEP and/or the AC and DC PDUs may be modular, such that defective units may be easily replaced.

In some embodiments, modular power distribution unit selection may provide a total power output of anywhere from 3.6 kW up to 36 kW, depending on how many modular power units are utilized. Single phase power may be up to 3.6 kW, and 3-phase wye/delta power may range from 6 kW up to 36 kW. Advantageously, the modular aspect of the PDUs may enable the same rack to accommodate a variety of different power profiles. As one example, a 3-phase power input to the PEP may be routed to three separate single phase AC PDUs, which may each have outlets that may be utilized to power the rack equipment and/or instruments. Each of the PEP, the AC PDUs, and the connective wiring between them may be housed within the side space.

In some embodiments 3-phase power output and various 12/24/48VDC voltage level outputs may be provided.

The modular side space power infrastructure design described herein may accommodate various customer needs in different fields such as transportation, semiconductors, etc. The side space design also enables a customer to fully utilize the primary rack space for mounting all measurement devices instead of using 2U worth of rack space in the primary housing to house the power supplies.

In some embodiments, the side space may be configured to accommodate input/output (I/O) devices and/or other connector operations, without using up the internal rack space of the housing. These devices may be installed in the side in a desired position to improve the user experience.

Test systems based on racks and cabinets often come with mass interconnects (MICs) used for attachment of fixtures used to interface DUTs (Devices Under Test) with test systems. In some embodiments, one or more MICs may be installed within the side space.

In some embodiments, the housing may be configured to fit standard rack mount equipment (e.g., 19 inch or another standard size) with standardized mounting options.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as embodiments. Elements and materials may be substituted for those illustrated and described herein, steps in processes and procedures may admit permutation of order, and certain features of the invention may be utilized independently, all as would be apparent to one skilled in the art after having the benefit of this description of the invention. Changes may be made in the elements described herein without departing from the spirit and scope of the invention as defined in the following claims.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A rack, comprising:
a housing configured to contain one or more instruments or equipment in a plurality of vertically stacked horizontal rows;
a side space arranged on a first side of the housing, wherein the side space comprises a rectangular space configured to house a plurality of power supplies, wherein the side space and the housing have substantially the same height and depth.

2. The rack of claim 1,
wherein the side space comprises a plurality of mounting rails configured to house the plurality of power supplies in a modular fashion.

3. The rack of claim 1, further comprising:
a hinged bracket attached to a first vertical edge of the side space and a second vertical edge of the housing, wherein the hinged bracket is configured to pivot the side space away from the housing,
wherein pivoting the side space away from the housing provides access to one or more of the plurality of power supplies and the one or more instruments or equipment without removing the plurality of power supplies from the side space or removing the one or more instruments or equipment from the housing.

4. The rack of claim 1,
wherein the side space has a thickness substantially close to two standardized rack units, and
wherein the horizontal rows of the housing are stacked with a vertical spacing of one standardized unit.

5. The rack of claim 1,
wherein the side space is further configured to house one or more input/output (I/O) devices.

6. The rack of claim 1,
wherein the side space comprises a hinged mounting bracket configured to hold a first power supply of the plurality of power supplies,
wherein the hinged mounting bracket is configured to pivot the first power supply away from the housing when holding the first power supply.

7. The rack of claim 1,
wherein the side space comprises one or more cooling vents to exhaust heat from the plurality of power supplies.

8. The rack of claim 1,
wherein the housing comprises a 19-inch horizontal rack space,
wherein the 19-inch horizontal rack space is adjacent to the side space.

9. The rack of claim 1,
wherein the housing is configured to house 15, 38, or 44 standardized units of instruments or equipment.

10. The rack of claim 1,
wherein the side space comprises a plurality of modular compartments, wherein each of the plurality of modular compartments have a substantially identical size and are configured to house a same type of power supply.

11. A side space, comprising:
a rectangular space configured to house a plurality of power supplies; and
a hinged bracket, wherein the hinged bracket is configured to attach the side space to a vertical edge of a housing of a rack, wherein the hinged bracket is configured to pivot the side space away from the housing to provide access to the plurality of power supplies without removing the power supplies from the rectangular space.

12. The side space of claim 11,
wherein the side space comprises a plurality of mounting rails configured to house the plurality of power supplies in a modular fashion.

13. The side space of claim 11,
wherein the side space has a thickness substantially close to two standardized rack units.

14. The side space of claim 11,
wherein the side space is further configured to house one or more input/output (I/O) devices.

15. The side space of claim 11,
wherein the hinged bracket comprises a hinged mounting bracket configured to hold a first power supply of the plurality of power supplies,
wherein the hinged mounting bracket is configured to pivot the first power supply away from the housing when holding the first power supply.

16. The side space of claim 11,
wherein the side space comprises one or more cooling vents to exhaust heat from the plurality of power supplies.

17. The rack of claim 1,
wherein the side space comprises a plurality of modular compartments, wherein each of the plurality of modular compartments have a substantially identical size and are configured to house a same type of power supply.

18. A rack, comprising:
a housing configured to contain one or more instruments or equipment in a plurality of vertically stacked horizontal rows;
a first side space attached to a first vertical edge of the housing via a first hinged bracket, wherein the first side space is configured to pivot on the first hinged bracket to a first position where the first side space overlays a left half of the housing and a second position where the first side space is pivoted away from the housing and provides access to the one or more instruments or equipment; and
a second side space attached to a second vertical edge of the housing via a second hinged bracket, wherein the second side space is configured to pivot on the second hinged bracket to a third position where the second side space overlays a right half of the housing and a fourth position where the second side space is pivoted away from the housing and provides access to the one or more instruments or equipment,
wherein the first and second side spaces comprise respective rectangular spaces configured to house a plurality of power supplies.

19. The rack of claim 1,
wherein the first and second side spaces have a thickness substantially close to two standardized rack units, and
wherein the horizontal rows of the housing are stacked with a vertical spacing of one standardized unit.

20. The rack of claim 18,
wherein the first and second side spaces each comprise a plurality of modular compartments, wherein each of the plurality of modular compartments have a substantially identical size and are configured to house a same type of power supply.
